(19) United States
(12) Patent Application Publication
(10) Pub. No.: US 2011/0233759 A1
(43) Pub. Date: Sep. 29, 2011

(54) SEMICONDUCTOR DEVICE

(76) Inventor: Toshitaka SHIGA, Niiza-shi (JP)

(21) Appl. No.: 12/825,901

(22) Filed: Jun. 29, 2010

(30) Foreign Application Priority Data
Mar. 23, 2010 (JP) 2010-066513

(51) Int. Cl. H01L 23/52; H01L 23/48

(52) U.S. Cl. 257/735; 257/E23.01; 257/E23.141

(57) ABSTRACT

All lead terminals 21 to 24 formed on a first side of a first radiator plate 31 are set as terminals D which are connected to one of the main electrodes of a power semiconductor chip 11 through which a switching current flows. A lead terminal 25 formed on a second side of the first radiator plate 31 is set as a terminal S connected to the other one of the main electrodes of the power semiconductor chip 11. A lead terminal 28 formed on the second side of the first radiator plate 31 is set as a terminal FB to which a control signal of a control IC chip 12 is input. Lead terminals 26 and 27 formed between the lead terminals 25 and 28 are set as a terminal Vcc and a terminal GND, respectively. In this configuration, the potentials at a portion where the lead terminal 26 and a bonding wire 50 connected to the lead terminal 26 exist and at a portion where the lead terminal 27 and a second radiator plate 32 connected to the lead terminal 27 exist are made constant, whereby a noise shield function for suppressing propagation of the switching noise is produced.

### BACKGROUND OF THE INVENTION

1. Field of the Invention

The present invention relates to a semiconductor device having a structure in which two semiconductor chips are incorporated in one package.

2. Description of the Related Art

In a power semiconductor module incorporating a power semiconductor element (rectification diode, power MOSFET, IGBT, etc.) that performs large current switching or large current rectification, the power semiconductor element generates a large amount of heat during operation. Thus, a power semiconductor module incorporating in a package a semiconductor chip having such a power semiconductor element is often configured to incorporate a control IC chip for safely controlling the power semiconductor element together with the semiconductor chip. In such a case, a temperature sensor, etc., is mounted on the control IC chip and, when the calorific value of the power semiconductor element is increased to a certain level, operation of the power semiconductor element is automatically stopped. With this configuration, it is possible to increase safety and reliability of the power semiconductor module that performs a large-current operation.

Such a configured power semiconductor module is disclosed in, e.g., Patent Document 1 (Japanese Patent, Publication No. 2005-44958). According to the disclosed power semiconductor module, a power semiconductor chip and a control IC chip incorporating a temperature sensor are mounted in contact with each other on a single radiator plate provided in an SIP (Single Inline Package). This configuration allows the control IC chip to detect a temperature rise of the power semiconductor chip with rapidity and accuracy, thereby enabling reliable control to be performed for the power semiconductor chip.

In such a semiconductor module, a high voltage is applied to terminals connected to the power semiconductor chip, and a large current flows between the terminals. Therefore, high-voltage resistance or high insulation property is required between the terminals, resulting in a reduction in layout flexibility. In order to cope with this problem, Patent Document 2 (Japanese Patent, Publication No. 2008-125315) discloses a DIP (Dual Inline Package)-type power semiconductor module having lead terminals arranged such that high-voltage side terminals are arranged along one side and low-voltage side terminals are arranged along the other opposing side.

By using the above techniques, a power semiconductor module having high safety and reliability can be obtained.

As described above, the power semiconductor element is driven with a high voltage (e.g., 400 V or higher), while a control IC (control IC chip) typically operates at several voltages lower than the voltage with which the power semiconductor element is driven. That is, although the power semiconductor chip and control IC chip are mounted close to each other in a single package, the operating voltages thereof significantly differ from each other.

ON/OFF operation is repeated at this high voltage in the power semiconductor chip, so that switching noise is likely to occur. When the switching noise is mixed into a control circuit of the control IC chip that operates at a comparatively low voltage, the control IC chip may malfunction. Such malfunction frequently occurs in the case where the power semiconductor module is miniaturized to reduce the interval between the power semiconductor chip and the control IC chip. In the technique disclosed in Patent Document 1, the power semiconductor chip and control IC chip are mounted in contact with each other, so that influence of the switching noise is significant. Also in the technique of Patent Document 2, influence of the switching noise cannot be suppressed.

In order to suppress occurrence of malfunction caused by the switching noise, it is effective to newly provide a structure for shielding the control IC chip from the noise. However, this approach complicates the manufacturing process of the power semiconductor chip or makes it difficult to achieve miniaturization of the power semiconductor chip due to necessity of providing the structure.

That is, it has been difficult to obtain a semiconductor device having reduced influence of the noise and increased reliability at low cost.

### SUMMARY OF THE INVENTION

The present invention has been made in view of the above problems, and an object thereof is to provide an invention that solves the above problems.

To solve the above problems, the present invention is configured as follows.

A semiconductor device according to the present invention includes: a first radiator plate; a second radiator plate disposed separately away from the first radiator plate; a plurality of first lead terminals arranged on a first side of the first radiator plate; a second lead terminal arranged on a second side of the first radiator plate that is opposite to the first side; a plurality of third lead terminals arranged on the second side and located closer to the second radiator plate than the second lead terminal; a first semiconductor chip that is mounted on the main surface of the first radiator plate, performs switching of a load connected to a high voltage, and includes a pair of main electrodes through which a main current in the switching operation flows; a second semiconductor chip that is mounted on the main surface of the second radiator plate, controls the switching operation of the first semiconductor chip, and operates at a lower voltage than the first semiconductor chip; and a mold material covering the first radiator plate, the second radiator plate, a part of the first lead terminals, a part of the second lead terminal, a part of the third lead terminals, the first semiconductor chip, and the second semiconductor chip. The first lead terminals and the second lead terminal and the third lead terminals are led out from a pair of sides of the mold material in the opposite directions to each other. The first radiator plate has an extending portion extending toward the side on which the second radiator plate is provided in the arrangement direction of the first lead terminals. At least one or more first lead terminals are connected to the first radiator plate. One main electrode of the pair of main electrodes of the first semiconductor chip that receives a higher voltage is connected to the first lead terminals, the other main electrode of the pair of main electrodes of the first semiconductor chip that receives a voltage closer to the ground potential is connected to the second lead terminal, and an electrode of the second semiconductor chip is connected to the third lead terminals.

In the semiconductor device according to the present invention, the plurality of third lead terminals includes: a lead terminal to which a power supply voltage of the second semiconductor chip is input; a lead terminal to which the ground potential is input; and a lead terminal to which a control signal for controlling the operation of the second semiconductor chip is input.

In the semiconductor device according to the present invention, on the second side of first radiator plate, at least one of the lead terminal to which a power supply voltage is input and lead terminal to which the ground potential is input is disposed at a location closer to the second lead terminal than to the lead terminal to which the control signal is input.

With the above configuration, a semiconductor device having reduced influence of noise and increased reliability can be obtained at low cost.

### BRIEF DESCRIPTION OF THE DRAWINGS

FIG. 1 is a view illustrating an example of a circuit constructed using a semiconductor module according to an embodiment of the present invention;

FIG. 2 is a top perspective view illustrating a configuration of the semiconductor module according to the embodiment of the present invention; and

FIG. 3 is a perspective view illustrating the outer appearance of the semiconductor module according to the embodiment of the present invention.

### DETAILED DESCRIPTION OF THE PREFERRED EMBODIMENTS

A semiconductor module will be described below as a semiconductor device according to an embodiment of the present invention. The semiconductor module of the embodiment has, in a package, two semiconductor chips (power semiconductor chip and control IC chip) which are mounted on individual radiator plates and are entirely sealed in a mold material.

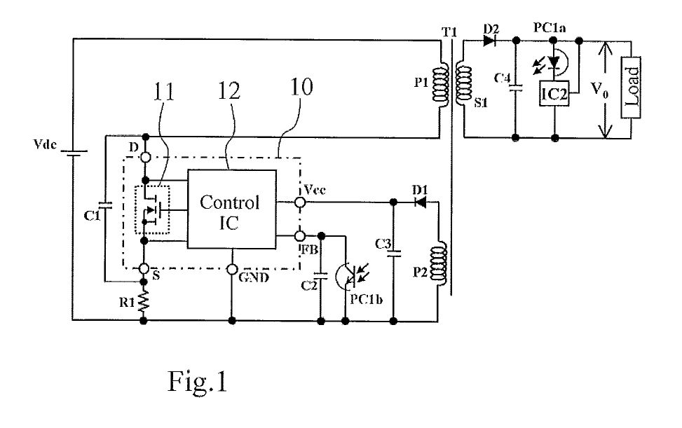

FIG. 1 illustrates an example of a power supply circuit (e.g., stand-by power supply circuit) realized by using the semiconductor module 10. In this circuit, the area surrounded by a dashed-dotted line corresponds to the semiconductor module 10 and includes a power semiconductor chip (first semiconductor chip) 11 and a control IC chip (second semiconductor chip) 12. In this circuit, an output voltage Vo is applied to a load presented in the upper right portion of FIG. 1.

The power semiconductor chip (first semiconductor chip) 11 is, e.g., a rectification diode, power MOSFET, and IGBT (Insulated Gate Bipolar Transistor) and has a terminal D connected to one end of a load which is connected to a high voltage. A terminal S has a potential closer to the ground potential than the terminal D. A control signal is supplied to the gate serving as the control terminal of the power semiconductor chip 11 to turn ON/OFF the power semiconductor chip 11, thereby controlling a switching current between the terminals D and S which are a pair of main electrodes. The control IC chip 12 supplies a control signal to the gate of the power semiconductor chip 11 to control the switching current.

The control IC chip (second semiconductor chip) 12 has a function of detecting a temperature rise of the power semiconductor chip 11 so as to control the power semiconductor chip 11. When a detected temperature is higher than a predetermined temperature, a control circuit formed in the control IC chip 12 forcibly turns OFF the power semiconductor chip 11. A power supply voltage for operating the control IC chip 12 is applied between terminals Vcc and GND (ground). A terminal FB receives a feedback signal allowing the control IC chip 12 to control the ON/OFF operation of the power semiconductor chip 11. The feedback signal is a return signal which is supplied from an error amplifier connected to the output terminal of the load so as to keep constant, e.g., the output voltage Vo of the load connected to the terminal D of the power semiconductor chip 11.

Thus, in the semiconductor module 10, five terminals of D, S, Vcc, FB, and GND are required, and they are distributed as the lead terminals. In the semiconductor module, the highest voltage is applied between the terminals D and S which are a pair of main electrodes of the power semiconductor chip 11 and therefore the largest current flows therebetween.

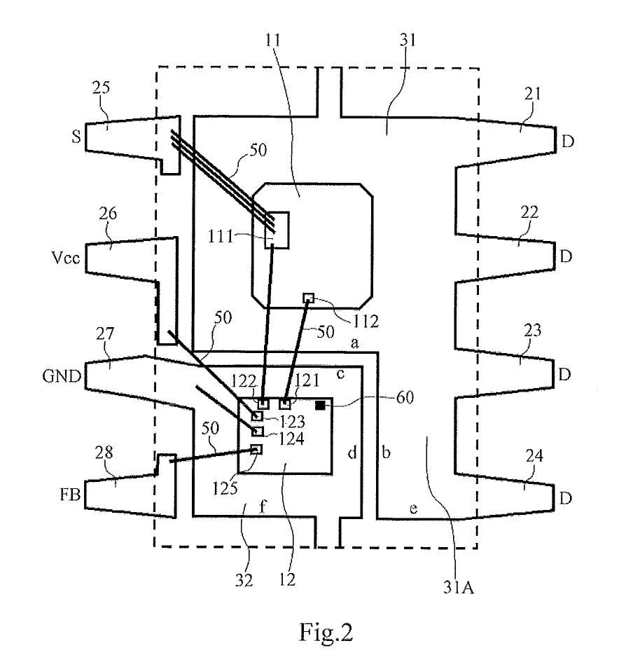

FIG. 2 is a top perspective view of the semiconductor module (semiconductor device) 10. The rectangular area surrounded by a broken line corresponds to the mold material made of resin. Four lead terminals 21 to 24 are led out from one side of the mold material, and four lead terminals 25 to 28 are led out from the other side in the opposite direction to the terminals 21 to 24. That is, the semiconductor module 10 is configured as a DIP (Dual Inline Package).

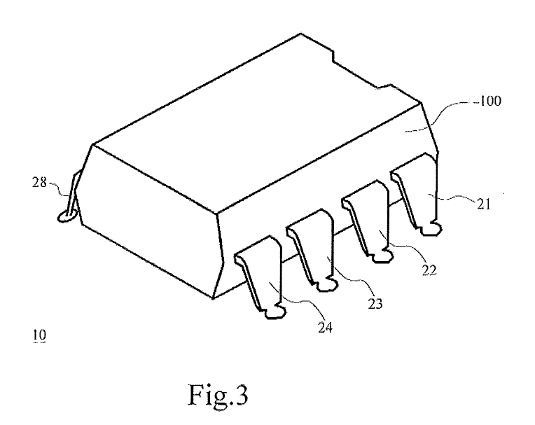

FIG. 3 is a perspective view of the outer appearance of the semiconductor module 10. As illustrated, in the semiconductor module 10, the lead terminals led out from the mold material 100 are subjected to lead forming (bending work), and the leading ends of the bent lead terminals are inserted into through-holes formed in a printed circuit board and fixed to the printed circuit board by soldering.

As illustrated in FIG. 2, in the semiconductor module 10, two radiator plates 31 and 32 are used. The power semiconductor chip (first semiconductor chip) 11 is mounted on the radiator plate (first radiator plate) 31 having a larger area, and the control IC chip (second semiconductor chip) 12 is mounted on the radiator plate (second radiator plate) 32 having a smaller area.

The lead terminals 21 to 28 are functionally classified into three terminal groups: a first lead terminal group (lead terminals 21 to 24), a second lead terminal group (lead terminal 25), and a third lead terminal group (lead terminals 26 to 28).

The first radiator plate 31 has an extending portion 31A extending toward the side on which the second radiator plate 32 is provided in the arrangement direction of the first lead terminals (lead terminals 21 to 24). Thus, in FIG. 2, a side a extending between a first side (right side) and a second side (left side) of the first radiator plate 31 comes close to and opposite to a side c of the second radiator plate 32. A side b constituting the extending portion 31A of the first radiator plate 31 comes close to and opposite to a side d of the second radiator plate 32. A side e at the leading end of the extending portion 31A and a side f of the second radiator plate 32 that is opposite to the side c are substantially collinear with each other. With the above configuration, it is possible to increase the heat dissipation efficiency of the power semiconductor chip 11, as well as to allow the control IC chip 12 to accurately detect a temperature rise.

However, the side e at the leading end of the extending portion 31A need not be collinear with the side f of the second radiator plate 32. The extending portion 31A exhibits its effect as long as the extending portion 31A extends, in the direction along the first side (right side) of the first radiator plate 31, at least up to a position at which the side d of the second radiator plate 32 having thereon the control IC chip 12 exists and the extending portion 31A and the side d are arranged with a gap interposed therebetween.

The first lead terminals (lead terminals 21 to 24) formed on the first side (right side) are integrally connected to the first radiator plate 31, while the second lead terminal (lead terminal 25) and the third lead terminals (lead terminals 26 to 28) formed on the second side (left side) opposite to the first side are not connected to the first radiator plate 31.

The second radiator plate 32 has its left side extending along the second side (left side) of the first radiator plate 31. One lead terminal 27 of the third lead terminals is connected to the second radiator plate 32, while the first lead terminals (lead terminals 21 to 24) are not connected thereto.

The radiator plates 31, 32 and lead terminals are manufactured by patterning a single metal plate. The metal plate is made of copper or copper alloy having a high electrical conductivity and a high thermal conductivity.

The power semiconductor chip 11 has on its surface bonding pads 111 and 112 connected to the elements inside thereof. Similarly, the control IC chip 12 has on its surface bonding pads 121 to 125. Electrical connections to the power semiconductor chip 11 and control IC chip 12 are made by connecting bonding wires to the bonding pads. In FIG. 2, bonding wires 50 are used to connect between the bonding pad 111 and lead terminal 25, between the bonding pad 111 and bonding pad 122, between the bonding pad 112 and bonding pad 121, between the bonding pad 123 and lead terminal 26, between the bonding pad 124 and second radiator plate 32, and between the bonding pad 125 and lead terminal 28. The rear surface (surface contacting the first radiator plate 31) of the power semiconductor chip 11 is also electrically connected to the first radiator plate 31. Further, the rear surface (surface contacting the second radiator plate 32) of the control IC chip 12 may electrically be connected to the second radiator plate 32. A plurality of bonding wires 50 are used at a portion (e.g., between the bonding pad 111 and lead terminal 25) where a large current flows.

In the semiconductor module 10, all the first lead terminals (lead terminals 21 to 24) are set as D terminals which are connected to one of the main electrodes of the power semiconductor chip 11 through which a switching current flows. The second lead terminal (lead terminal 25) formed on the second side is set as a terminal S connected to the other one of the main electrodes of the power semiconductor chip 11.

The lead terminal 28, which is one terminal of the third lead terminals formed on the second side, is set as a terminal FB to which the control signal of the control IC chip 12 is input. The lead terminals 26 and 27 formed between the lead terminals 25 and 28 are set as a terminal Vcc and a terminal GND, respectively. The terminals are used to apply a power supply voltage for operating the control IC chip 12.

In the semiconductor module 10, switching noise is generated by a switching current flowing between the terminals D and S serving as the main electrodes. Although the terminals D and S are not directly connected to the control IC chip 12, the switching noise may propagate in the air (in the mold material 100) and reach the control circuit formed in the control IC chip 12. Further, when the switching noise is mixed with the control signal to be applied to the terminal FB, the control IC chip may malfunction.

In the above configuration, the terminals D (lead terminals 21 to 24) each have the same potential as that of the first radiator plate 31, and the terminal S (lead terminal 25) has the same potential as those of the bonding pad 111 and the bonding wire 50 connected to the bonding pad 111. The above terminals D and S can be a source of the switching noise.

In the configuration of FIG. 2, there exist between the above terminals and control IC chip 12 the terminal Vcc (lead terminal 26), bonding wire 50 connected to the terminal Vcc, terminal GND (lead terminal 27), and second radiator plate 32 connected to the terminal GND. The terminal GND is grounded. A constant low voltage is applied as a power supply voltage to the terminal Vcc. As illustrated in FIG. 1, a bypass capacitor C3 is generally provided between the terminals Vcc and GND. Thus, in the configuration of FIG. 2, the potentials at a portion where the lead terminal 26 and the bonding wire 50 connected to the lead terminal 26 exist and at a portion where the lead terminal 27 and the second radiator plate 32 connected to the lead terminal 27 exist are made constant, whereby a noise shield function for suppressing propagation of the switching noise is produced. The lead terminal 28 (terminal FB) formed on the lower end portion (other end portion) on the left side is shielded by the shielding portions, thereby preventing the switching noise from being mixed with the control signal of the control IC chip 12. In addition, separation of the first radiator plate 31 and second radiator plate 32 contributes to the suppression of the propagation of the switching noise.

In such a configuration, a portion where the switching noise is most likely to be mixed with the control signal of the control IC chip 12 is the bonding wire 50 connected to the lead terminal 28 (terminal FB). However, in the configuration of FIG. 2, the interval between the control IC chip 12 (bonding pad 125) and the lead terminal 28 can be made smaller and, accordingly, the length of the bonding wire 50 connecting the bonding pad 125 and the lead terminal 28 can be reduced. Therefore, it is possible to reduce noise generated from the bonding wire 50. The noise mentioned here is not limited to the switching noise but includes noise generated outside the semiconductor module 10, e.g., noise generated by thunder or a commercial AC source. Further, such external noise is easily mixed into the first radiator plate 31 having a larger area. Also in this case, however, this external noise is shielded for the same reason as in the case of the switching noise. Thus, in the configuration described above, it is possible to ensure a high resistance to both noise generated inside the semiconductor module and noise generated outside thereof.

In the above configuration, the above effect can be achieved without additionally providing a structure such as a noise shield, but by only adding new twists to the configurations of the radiator plates and lead terminals. That is, a high-reliable semiconductor module can be obtained at low cost.

Although the power semiconductor chip is the first semiconductor chip and the control IC chip controlling the power semiconductor chip is the second semiconductor chip in the above example, the present invention is not limited to this. It is clear that the same effect can be attained as long as a semiconductor module (semiconductor device) has a configuration in which a semiconductor chip that can be a noise source is used as the first semiconductor chip, a semiconductor chip to which the noise generated from the first semiconductor chip is prevented from being mixed is used as the second semiconductor chip, and the first and second semiconductor chips are encapsulated in a single package.

Further, a lead terminal to which the ground potential or constant potential is applied is provided between the lead terminal connected to the power semiconductor chip 11 that can be a noise source and the terminal FB to which the control signal of the control IC chip is input. Although the terminal GND and terminal Vcc correspond to this in the above example, the same effect can be attained even when only one of the terminals GND and Vcc is provided. In the case where both the terminals GND and Vcc are provided, the same effect can be attained irrespective of the order of their arrangement. Further, the positional relationship among the above lead terminals in the horizontal or vertical direction may be reversed.

With the configuration described above, it is possible to reduce influence of noise in a semiconductor module incorporating two semiconductor chips.

Although FIG. 2 illustrates a DIP configuration in which the lead terminals are symmetrically arranged, the lead terminals may asymmetrically be arranged on the both sides.

Further, in the case where the first semiconductor chip is a power semiconductor chip generating a large heat amount, it is possible to increase the safety and reliability of the semiconductor module in the configuration of FIG. 2 also from a viewpoint other than a reduction in the influence of noise. This point will be described in the following.

In the configuration of FIG. 2, heat generated in the power semiconductor chip 11 is transmitted to the first radiator plate 31 to be released. At this time, the heat is also released through the lead terminals 21 to 24 connected to the first radiator plate 31 and led outside as illustrated in FIG. 3. Thus, a high heat dissipation efficiency can be achieved in the configuration of FIG. 2, thereby suppressing a temperature rise of the power semiconductor chip 11. The control IC chip 12 is a common IC chip and it is preferable not to increase the temperature of the control IC chip 12 to a high value for stable operation. In the configuration of FIG. 2, the entire temperature of the radiator plates 31 and 32 can be reduced, thereby preventing the operation of the control IC chip 12 from being adversely affected.

In order to increase the safety of the semiconductor module 10, it is necessary for a temperature sensor 60 installed in the control IC chip 12 to sensitively detect a temperature rise of the power semiconductor chip 11 or first radiator heat 31. To this end, it is effective to install the temperature sensor 60 existing on the second radiator plate 32 at the first radiator plate 31 side portion of the control IC chip 12. Thus, it is particularly preferable that the side a of the first radiator plate 31 and side c of the second radiator plate 32 in FIG. 2, or the side b of the first radiator plate 31 and side d of the second radiator plate 32 in FIG. 2 be made close to each other, and that the temperature sensor 60 be installed near the side c or side d. With this configuration, the control IC chip 12 can control the operation of the power semiconductor chip 11 particularly safely, thus resulting in an increase in the safety of the semiconductor module 10.

The second radiator plate has any shape as long as the semiconductor module having the configuration described above can be obtained and the first and second radiator plates can be combined with each other. For example, the second radiator plate may be formed into a circular or semicircular shape. As to the first radiator plate, the shape around one vertex of the plate is made to match the shape of the second radiator plate.

Further, although the power semiconductor chip (first semiconductor chip) and control IC chip (second semiconductor chip) are mounted to the first and second radiator plates, respectively, in the above example, a chip (or chips) other than the power semiconductor chip and control IC chip may be mounted on each radiator plate. In this case, it is preferable that a semiconductor chip that can be a noise source be mounted on the first radiator plate and a semiconductor chip as a noise influence reduction target be mounted on the second radiator plate.

What is claimed is:

1. A semiconductor device comprising:
a first radiator plate;
a second radiator plate disposed separately away from the first radiator plate;
a plurality of first lead terminals arranged on a first side of the first radiator plate;
a second lead terminal arranged on a second side of the first radiator plate that is opposite to the first side;
a plurality of third lead terminals arranged on the second side and located closer to the second radiator plate than the second lead terminal;
a first semiconductor chip that is mounted on the main surface of the first radiator plate, performs switching of a load connected to a high voltage, and includes a pair of main electrodes through which a main current in the switching operation flows;
a second semiconductor chip that is mounted on the main surface of the second radiator plate, controls the switching operation of the first semiconductor chip, and operates at a lower voltage than the first semiconductor chip; and
a mold material covering the first radiator plate, the second radiator plate, a part of the first lead terminals, a part of the second lead terminal, a part of the third lead terminals, the first semiconductor chip, and the second semiconductor chip,
the first lead terminals, second lead terminal and third lead terminals being led out from a pair of sides of the mold material in the opposite directions to each other, wherein
the first radiator plate has an extending portion extending toward the side on which the second radiator plate is provided in the arrangement direction of the first lead terminals,
at least one or more first lead terminals are connected to the first radiator plate,
one main electrode of the pair of main electrodes of the first semiconductor chip that receives a higher voltage is connected to the first lead terminals, the other main electrode of the pair of main electrodes of the first semiconductor chip that receives a voltage closer to the ground potential is connected to the second lead terminal, and an electrode of the second semiconductor chip is connected to the third lead terminals.

2. The semiconductor device according to claim 1, wherein
the plurality of third lead terminals includes:
a lead terminal to which a power supply voltage of the second semiconductor chip is input;
a lead terminal to which the ground potential is input; and
a lead terminal to which a control signal for controlling the operation of the second semiconductor chip is input.

3. The semiconductor device according to claim 2, wherein
on the second side of first radiator plate, at least one of the lead terminal to which a power supply voltage is input and the lead terminal to which the ground potential is input is disposed at a location closer to the second lead terminal than to the lead terminal to which the control signal is input.
